(19) United States
(12) Patent Application Publication
(10) Pub. No.: US 2021/0344318 A1
(43) Pub. Date: Nov. 4, 2021

(54) Piezo Magnetic Resonator/Amplifier

(71) Applicant: Timothy J Gindele, Hillsboro, OH (US)

(72) Inventor: Timothy J Gindele, Hillsboro, OH (US)

(21) Appl. No.: 15/929,370

(22) Filed: Apr. 29, 2020

(51) Int. Cl. H03H 3/04; H04R 17/10

(52) U.S. Cl. CPC H03H 3/04; H04R 17/10

(57) ABSTRACT

The piezoelectric effect is a well-known phenomenon inherent in some crystal compounds. Silicon dioxide in nature forms a natural hexagonal crystal. The same material when heated to a molten state and then rapidly cooled becomes common glass with no piezoelectric effect. The phenomenon is an electrical or electron relationship to the crystal in that when the modulus is changed the state of electrical charge also changes and in two modalities. If you apply an electrical charge the crystal will change shape and if you change the shape the crystal it will cause an electrical charge.

The device being presented is part of a larger thesis of the phenomenon in that it is presenting mechanical interactivity from low to ultrahigh frequencies. It was also discovered that the reactance of the crystal can be produced under magnetic pressure such that stacking crystals between strong magnets called unit/cells and connecting them in a series/parallel wired conductive arrangement can produce an amplification such that all frequencies of electrical activity in the environment are amplified and produce a rectifiable current flow of electrons.

Envisioned are many possible embodiments of this device. One such embodiment is the application of a coupled toroidal coil that enhances the signals in the environment and magnetically couples the signal into the device.

This device has been prototyped and functions as described. The output characteristics beyond what has been described are not disclosed and are considered proprietary information.

### REFERENCES CITED

### U.S. Patent Documents

| | | |
|---|---|---|
| 10,044,290 B2 | August 2018 | Finocchioro |
| 10,250,224 B2 | April 2019 | Kaga |
| 10,027,331 B2 | June 2018 | Yonezawa et al |
| 10,256,787 B2 | April 2019 | Chang |
| 10,227,197 B2 | April 2019 | Kaga |
| 10,305,446 B2 | May 2019 | Lee et al |
| 10,322,432 B2 | May 2019 | Hogan et al |
| 10,404,192 B2 | September 2019 | Martin |
| 10,447,135 B2 | October 2019 | Yuksek et al |
| 10,447,179 B2 | October 2019 | Rastegar et al |
| 10,512,297 B2 | December 2019 | Vamvas |
| 10,505,471 B2 | December 2019 | Emami et al |
| 10,581,347 B2 | March 2019 | Rastegar et al |

### BACKGROUND OF THE INVENTION

### 1. Field of the Invention

The invention provides a mechanism by which piezo reactive crystals are juxtaposed to magnets in a series/parallel embodiment and electrically coupled to produce and amplification of electrical energy. In conjunction with a special embodiment of a soft steel core toroidal coil configured in placement against the series magneto/piezo device the device produces a self-generating electrical resonance with no external electrical source of power.

Summary—This invention produces electrical energy as the piezo reactive units called transducers resonate against the rare earth (neodymium) magnets. The embodiment can consist of any number of unit/cells in a series/parallel configuration. A unit/cell is two magnets with a piezo transducer placed between the magnets. The assembled system produces amplification of signals inherent in our earth and atmosphere such as low frequency house current noise to ultrahigh frequencies in radar transmissions as well as magnetic fluctuations. The gain that is achieved is currently classified since research is being conducted. An included embodiment in the invention is a unique toroidal coil that is attached to the ends of an assembly of units that further enhances the signals produced. The device is self-generating and produces as much as 500 millivolts peak-to-peak at low frequencies and attenuates to 50 millivolts at frequencies as high as 30 gigahertz. The current is nominal at 1 to 10 milliamps.

The device is a reactive component and is being researched as an active capacitor or as a current bounce back springboard current enhancer.

### 2. Search Criteria and Description of Prior Art

References cited in the search give examples of devices that use the piezoelectric phenomenon to accomplish their stated goals.

Careful examination and the supplied abstract analysis will describe how all prior art and scientific presentations do not attempt to achieve the unique function of this invention and are not relevant.

### BRIEF DESCRIPTION OF DRAWING FIGURES

FIG. 1—The transducer

FIG. 2—One Magneto/piezo unit

FIG. 3—Example of multiple stages

FIG. 4—Prototype incorporating toroid coil

### CATALOG OF ITEM NUMBERS

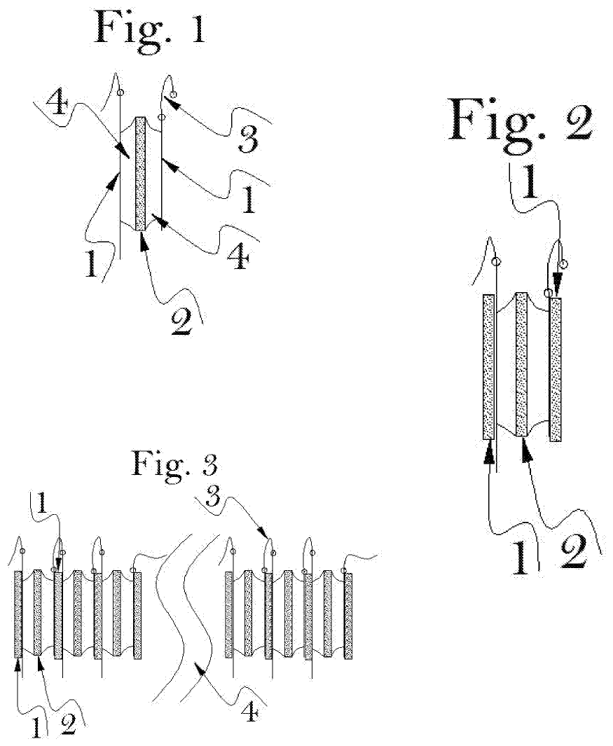

### FIG. 1—The Transducer

1—Conductor plate

2—Piezo material

3—Connection lead

4—Bonding agent

### FIG. 2—The Magneto/Piezo Unit

1—Magnet

2—Piezo material

### FIG. 3 Example of Multiple Stages

1—Magnet

2 —Piezo transducer

3 —Connection lead

4 —Separation line indicating multiple units between.

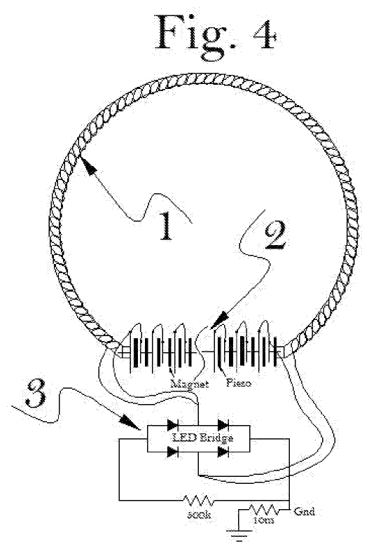

### FIG. 4 Example of Prototype Incorporating the Toroid Coil

1—Toroid Coil

2—Complete assembly using many units

3—Simple test circuit with LED (light emitting diodes) indicators.

### INVENTION DETAILED DESCRIPTION

In conjunction with a larger thesis on the nature of magnetism and dark matter fields this device was conceived to see the interaction of magnetic pressure on piezo materials. In researching the phenomenon it was discovered that signal activity was generated simply by placing strong magnets on either side of a piezo active material.

It was a simple consideration that by placing a series of what were then termed units and connecting them electrically from one to the next that an amplification occurred. The amount of the increase in signal in both volts and amps is calculable and is now maintained as proprietary information.

All embodiments of large arrays of series and parallel arrangements are considered here. Though the toroidal coil is not essential for the operation, it shows additional amplification when it is used as opposed to operating the system as magneto/piezo units independently.

Research into magneto/piezo units is ongoing but of consideration is the embodiment of larger dimension units as well as micro dimension units. Of note is the magnetic fluctuations discovered other than what can be recognized as common electromagnetic radiation being generated by commercial enterprises such as radio stations, telephone networks and weather radar installations. Frequencies have been amplified that are in the q-band of 33-50 gigahertz at amplitudes that are beyond the possible limits in the earth's atmosphere. This will not be sought as a claim since research is on-going in dark matter fields. For proprietary reasons dimension, exact materials and values are not germane to this presentation.

Refer to FIG. 1. This is a simple detail of a piezo material (2) such as quartz or langasite or most common in transducers is lead titanate bonded with a conductive agent (4) to a conducting plate (1) which has a connected wire lead (3) for interconnecting units.

Refer to FIG. 2. This shows a unit/cell (2) with two neodymian magnets (1) placed on either side of the unit.

Refer to FIG. 3. This shows the stacking of unit/cells. The drawing shows the magnets (1) between each piezo transducer (2) and the wire leads (3) connected. Arrow (4) indicates a break in the drawing to indicate that there are many unit/cells incorporated but not show.

Refer to FIG. 4. This shows an assembly incorporating the soft steel core toroidal coil (1) as it is attached to an array of unit/cells (2). A simple LED (light emitting diode) bridge rectifier (3) as a test circuit is shown with a 500 kilo-ohm resistor as a load and a 10 megaohm limited earth ground point.

1. The herein described Piezo Magnetic Resonator/Amplifier produces electrical energy with no external source of power. This device/invention is unique to any and all prior art that has be awarded patent protection.
